(19) United States
(12) Patent Application Publication
(10) Pub. No.: US 2022/0376468 A1
(43) Pub. Date: Nov. 24, 2022

(54) LASER EMITTER ASSEMBLY AND LIDAR SYSTEM

(71) Applicant: Robert Bosch GmbH, Stuttgart (DE)

(72) Inventors: Thomas Maurer, Stuttgart (DE); Frederik Ante, Ludwigsburg (DE); Markus Kienzle, Lehrensteinsfeld (DE)

(21) Appl. No.: 17/765,027

(22) PCT Filed: Oct. 23, 2020
(86) PCT No.: PCT/EP2020/079919

§ 371 Date: Mar. 30, 2022

(30) Foreign Application Priority Data
Nov. 4, 2019 (DE) 10 2019 216 924.4

(51) Int. Cl. H01S 5/024; G05D 23/02; G01S 7/481

(52) U.S. Cl. CPC H01S 5/02415; G05D 23/02; G01S 7/4814; H01S 5/02469; H01S 5/02453; H01S 5/02315

(57) ABSTRACT

A laser emitter assembly that has a laser emitter and a support for the laser emitter. The support has a multiplicity of layers. One of the layers is a thermomechanical door that is designed to thermally regulate the laser emitter. A LiDAR system, to the power supply of which the laser emitter assembly is operatively connected, is also described.

### FIELD

The present invention relates to a laser emitter assembly that has a laser emitter and a support for the laser emitter, the support having a multiplicity of layers, and also to a LiDAR system having such a laser emitter assembly, the laser emitter assembly being operatively connected to a power supply of the LiDAR system.

### BACKGROUND INFORMATION

Laser emitters having a high electrical power loss typically require special measures preventing the laser components from overheating.

Conventionally, the laser temperature can be regulated by means of a Peltier element. At very high ambient temperatures, also referred to as a high temperature situation, the Peltier element serves to cool the laser emitters. At very low temperatures, also referred to as a low temperature situation, the Peltier element helps to bring the laser emitters to an operating temperature by supplying additional heat output. Thus the Peltier element in the context of laser temperature control represents a thermal switch for switching between heating and cooling.

In the high temperature situation, a cooling face of the Peltier element requires as homogeneous as possible a temperature distribution. Frequently, for this purpose heat spreaders are placed between a laser ceramic, which may take the form of a laser ceramic layer, and the Peltier element. The heat spreader serves to spread the heat from one edge of the laser substrate laterally over the entire congruent Peltier surface and to guarantee a sufficient homogeneous temperature distribution on the cold side of the Peltier element. If this homogeneous temperature distribution is not achieved, the power loss of the Peltier element increases exponentially and makes it difficult to regulate the thermal management, with lasting effect.

In the low temperature situation, a heating face of the Peltier element requires as short as possible a heat conduction path to the laser emitter. The heat spreader required for the high temperature case represents an additional and unnecessary thermal resistance in this case.

German Patent No. DE 3431738 A1 describes a device for cooling a support for at least one component, for example a laser diode. The specification addresses heat flows in such components and the need for Peltier elements, the intention being to reduce the power requirement of the Peltier element.

A housing arrangement for a laser module is described in German Patent No. DE 19823691 A1. In order to reduce effects of heat, it is proposed to foam-coat, or alternatively encapsulate, the housing arrangement with a poorly thermally conductive plastics material, as a result of which a Peltier cooler can also be thermally insulated.

German Patent No. DE 69736015 T2 describes a semiconductor laser module for emitting a laser beam, wherein a cooling body can be arranged between a Peltier element and a semiconductor laser in order further to suppress a change in temperature of the semiconductor laser.

DE 10 2005 036 099 A1 describes an apparatus for controlling the temperature of a laser module in a printing plate exposer. The problem is mentioned that a cooling device should be provided in order to cool the laser diode, but owing to the design there is not enough space for a Peltier element. Therefore it is proposed to externalize the Peltier element by attaching it via a heat conduit.

A cooling device for a laser headlight of a motor vehicle is described in DE 10 2013 216869 A1. One idea disclosed therein is to replace active cooling systems, such as for example Peltier elements or cooling fans, with passive cooling. As a result, one or more passive air guides, i.e. ones without a fan, are provided on the headlight.

German Patent Application No. DE 203 16 550 U1 describes a laser element in which a laser-active medium is connected for heat conduction in the manner of a sandwich to two components consisting of diamond disks. By means of this diamond cooling, waste heat can be conducted away from the laser-active medium without a Peltier element.

DE 10 2004 052 094 A1 describes a laser element in which a laser-active medium is generally embedded in a thermally conductive crystalline material, which is comparable to the one described in German Patent Application No. DE 203 16 550 U1 mentioned above.

Finally, a semiconductor component that is designed to emit electromagnetic radiation is described in German Patent Application No. DE 10 2007 041 896 A1. One or more cooling layers are provided, and may be partly transparent. For instance, a cooling layer, divided into two, made of metallic material or a ceramic material is provided. The cooling layers are thermally connected to a heat sink. The cooling layers may have a cavity that is filled at least partly with a cooling liquid.

### SUMMARY

According to the present invention, a laser emitter assembly is made available in which one of the layers is a thermomechanical door that is designed to thermally regulate the laser emitter.

The laser emitter assembly according to the present invention has an advantage that the necessary cooling and heating phases of the laser emitter are thermally optimized and adapted to the respective application. The thermomechanical door, by blocking heat flows or allowing them through, replaces the functionalities of a Peltier element: cooling and heating. As a result, use of the Peltier element is considerably reduced, or even avoided completely. This results in lower power losses from the entire system, and thereby significantly simplifies the thermal management.

In accordance with an example embodiment of the present invention, preferably, the thermomechanical door is opened in a high temperature situation and is closed in a low temperature situation. The task of the thermomechanical door, in the high temperature situation, that is to say when there is a high cooling requirement for the laser emitter, may be to implement the required dissipation of heat from the laser emitter. This may mean opening the required heat path only as far as is required. In the high temperature situation, therefore, preferably the thermomechanical door is at least partly opened, particularly preferably is completely opened. In the low temperature situation, that is to say heating of the laser emitter, dissipation of heat from the laser emitter should preferably be prevented, so that it can heat up to a required operating temperature independently by internal heating, and preferably no parasitic heat flows to adjoining components can be produced. In the low temperature situation, therefore, preferably the thermomechanical door is at least partly closed, particularly preferably is completely closed.

In accordance with an example embodiment of the present invention, it is preferred for the thermomechanical door to have two door planes that are displaceable in relation to each other in order to open or close the thermomechanical door. The thermomechanical door preferably is made of two parts: an upper door plane and a lower door plane that is identical, but offset relative to the upper door plane. It is preferred for both door planes to consist of the same material, in order to achieve as homogeneous as possible a heat flow in the opened state, that is to say when there is contact between the upper door plane and the lower door plane. If the same material is used, in addition possible electrochemical corrosion can be avoided. Preferably breaks are provided within each door plane, the breaks in the operating state being located substantially opposite material of the adjoining other door plane.

In accordance with an example embodiment of the present invention, it is preferred, in the open state of the door, for gaps between the two door planes to be closed and the material of the two door planes to overlap laterally in portions. Preferably the gaps are opened in the closed state of the door. In the low temperature situation, the laser emitter should as far as possible reach the necessary operating temperature by its internal heating. Therefore the specific heat that it generates should not be given off to the adjoining components. Therefore it is preferred, as set forth above, for the thermomechanical door to be closed in the low temperature situation. Thus in the low temperature case there is preferably no thermomechanical contact between the upper and lower door plane of the thermomechanical door. In the high temperature situation, the power loss of the laser emitter should be conducted away from the laser emitter as effectively as possible. For this, it is advantageous if the upper door plane and the lower door plane of the thermomechanical door in the high temperature situation are in touching contact with each other over as large an area and as securely as possible. Thus in the high temperature situation there is preferably thermomechanical contact between the upper door plane and the lower door plane of the thermomechanical door. Therefore the thermomechanical door is preferably opened so far (size of the contact face of both door planes) as is required for the high temperature situation. The larger the contact face of the first door plane with the second door plane, the further the thermomechanical door is opened. With a maximum contact face, the thermomechanical door is preferably completely opened. With a minimum contact face, the thermomechanical door is preferably closed as far as possible. If there is no contact face between the first door plane and the second door plane, the thermomechanical door is preferably completely closed.

In specific embodiments of the present invention, the thermomechanical door is designed to be opened and closed by lateral contraction and expansion of the two door planes. The opening and closing of the thermomechanical door is preferably implemented by the expansion and contraction of the upper and lower door planes in changing ambient temperatures, i.e., is preferably dependent on ambient temperature. In the low temperature situation, the contact between both door planes is preferably released. Then heat transfer between the upper and lower door plane is not possible, that is to say the thermomechanical door is closed. In the high temperature situation, the opposite is true. That is to say, due to the higher external temperatures, the two door planes preferably expand laterally, perpendicularly to a direction of stacking of the layers, and a thermomechanical contact is formed. At this contact point, there is thus a direct heat transfer from the heat source, i.e., the laser emitter, to the heat sink layer. In the high temperature case, the thermomechanical door is thus preferably at least partly opened, as already mentioned.

In some specific embodiments of the present invention, at least one of the two door planes comprises a phase change material. When both sides are contacted, skewing of the upper and lower door plane may occur. In order to avoid this, a phase change material (PCM) may be inserted on one of the two door planes or alternatively on both door planes. The phase change material is a latent heat store.

Some specific embodiments of the present invention have the phase change material arranged between the two door planes. The phase change material can then level out very minor irregularities between the upper and lower door plane by melting the material, which improves in particular the surface contact between the two door planes, and preferably increases the heat exchange. The PCM thus preferably serves to smooth the transition between the states of the thermomechanical door from open to closed and vice versa.

Preferably the thermomechanical door is arranged between a laser ceramic layer and a heat sink layer. The thermomechanical door can then replace both the Peltier element and the Peltier-relevant heat spreader. As a result, the structure of the entire laser emitter assembly is reduced by one layer. On the one hand, the required cooling and heating function continues to be provided by the thermomechanical optimization of the thermomechanical door. On the other hand, the major disadvantages of the Peltier element, high additional power loss and additional control means, are avoided and thus the overall configuration is considerably simplified, with lasting effect. The laser emitter is preferably arranged directly on the laser ceramic layer. The laser ceramic layer preferably comprises Al₂O₃ or AlN.

In preferred specific embodiments of the present invention, a heating element is arranged between the thermomechanical door and the heat sink layer. The heating element is preferably arranged in a heating element layer. It is possible that in the low temperature situation the internal heating of the laser is not sufficient to achieve the operating temperature in a timely manner. In order to guarantee an inertial heat output that may be lacking, a heating element can be inserted between the underside of the thermal door and the heat sink layer. Due to the additional power loss, the lower door plane expands more greatly than the upper door plane. The contact between the two door planes is closed and an additional flow of heat from the lower to the upper door plane takes place. The flow of heat is then transmitted to the laser emitter. If the laser emitter reaches its operating temperature, the additional heating element is switched off, the lower door plane contracts again and the thermomechanical door is closed again.

In some specific embodiments of the present invention, a Peltier element is arranged between the thermomechanical door and the heat sink layer. The Peltier element is preferably arranged in the heating element layer. If both further heat output is required in the low temperature situation and additional cooling capacity is required in the high temperature situation, a Peltier element may again be provided instead of the additional heating element. The additional power loss of the Peltier element is however significantly reduced by combining it with the thermomechanical door, and thus handling of the thermal management is simplified.

It is preferred for the laser emitter assembly to be configured as a laser module. Thus the laser emitter assembly can be newly installed or be replaced in a compact manner in particular in LiDAR systems. The support preferably, when viewed starting from the laser emitter, has the laser ceramic layer, the thermomechanical door and the heat sink layer as functional layers. The laser ceramic layer is preferably joined to the upper door plane by means of a first adhesive layer. The heat sink layer is preferably joined to the lower door plane by means of a second adhesive layer. In specific embodiments, a heating element layer may be provided between the heat sink layer and the thermomechanical door. The heating element layer is then preferably joined to the heat sink layer and the lower door plane by gluing. The heating element layer may have in particular the heating element or the Peltier element, in so far as additional heating or alternatively cooling of the laser emitter from the support is desired. The thermomechanical door is preferably formed from a material that, in the necessary layer form, has sufficient lateral thermal expansion to guarantee the temperature-dependent overlapping and spacing apart of the two door elements. Such materials are conventional to a person skilled in the art.

According to the present invention, a LiDAR system of the type referred to first hereinbefore is provided in which one of the layers of the laser emitter assembly is a thermomechanical door that is designed to thermally regulate the laser emitter.

The LiDAR system according to an example embodiment of the present invention has the advantage that the necessary cooling and heating phases of the laser emitter are thermally optimized and adapted to the respective application. The thermomechanical door, by blocking heat flows or allowing them through, replaces the functionalities of a Peltier element: cooling and heating. As a result, use of the Peltier element is considerably reduced, or even avoided completely. This results in lower power losses from the entire system, and thereby significantly simplifies the thermal management.

The same possible specific embodiments and the associated advantages that have already been described above with regard to the laser emitter assembly and to which reference is made here are yielded for the LiDAR system. Repetition will therefore be dispensed with at this point.

The present invention can be used in particular in conjunction with all components/sensors that use a laser emitter, in particular in macro-scanner LIDAR systems and for example in automotive LiDAR platform development.

Advantageous developments of the present invention are disclosed herein.

### BRIEF DESCRIPTION OF THE DRAWINGS

Embodiment examples of the present invention will be discussed in greater detail with reference to the figures and the following description.

FIG. 1 shows a first specific embodiment of the laser emitter assembly, which has a heating element, in accordance with the present invention.

FIG. 2 is a detail view of a closed thermomechanical door in the specific embodiment of FIG. 1, in accordance with the present invention.

FIG. 3 is a detail view of an open thermomechanical door in the specific embodiment of FIG. 1, in accordance with the present invention.

FIG. 4 shows a second specific embodiment of the invention, which has a Peltier element, in accordance with the present invention.

### DETAILED DESCRIPTION OF EXAMPLE EMBODIMENTS

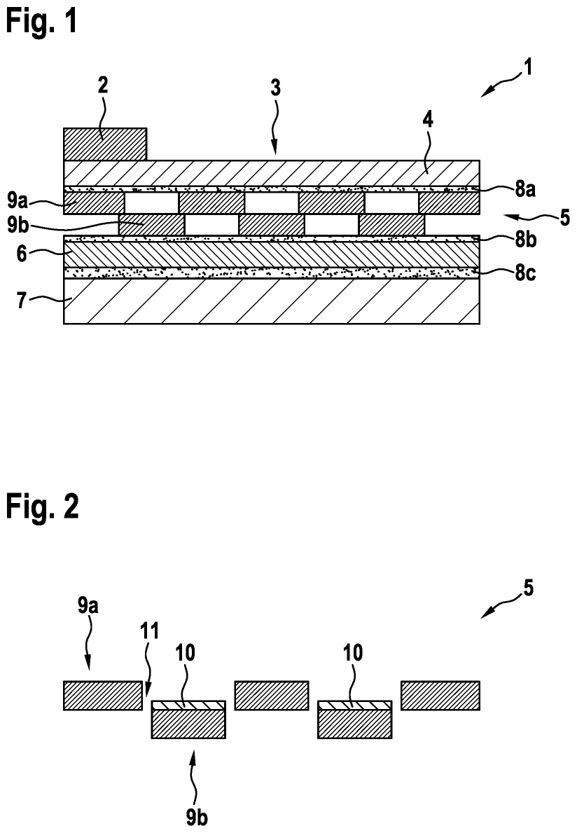

FIG. 1 shows a first specific embodiment of the laser emitter assembly 1. The laser emitter assembly 1 is part of a LiDAR system, not illustrated further, to the power supply of which the laser emitter assembly 1 is operatively connected.

The laser emitter assembly 1 has a laser emitter 2. The laser emitter 2 is operatively connected to the power supply of the LiDAR system. The laser emitter assembly 1 further has a support 3 for the laser emitter 2. The support 3 has a multiplicity of layers 4, 5, 6, 7, 8a-c. The layers 4, 5, 6, 7, 8a-c are stacked one above another. Starting from the laser emitter 2, they are, in descending order, a laser ceramic layer 4 that is formed of Al₂O₃, a thermomechanical door 5 that is designed to thermally regulate the laser emitter 2, a heating element layer 6, and a heat sink layer 7. The thermomechanical door 5 is therefore arranged between the laser ceramic layer 4 and the heat sink layer 7. Between the aforementioned functional layers are arranged adhesive layers 8a-c. A first adhesive layer 8a joins the laser ceramic layer 4 to the thermomechanical door 5. A second adhesive layer 8b joins the thermomechanical door 5 to the heating element layer 6. A third adhesive layer 8c connects the thermomechanical door 5 to the heat sink layer 7. The laser emitter 2 is arranged directly on the laser ceramic layer 4, so that the support 3 bears the laser emitter 2 by means of the laser ceramic layer 4.

The thermomechanical door 5 is opened in a high temperature situation and closed in a low temperature situation. Thus heat can be accumulated in the laser emitter 2 in the low temperature situation, and in the high temperature situation can be dissipated from the laser emitter 2 through the thermomechanical door 5 to the heat sink layer 7.

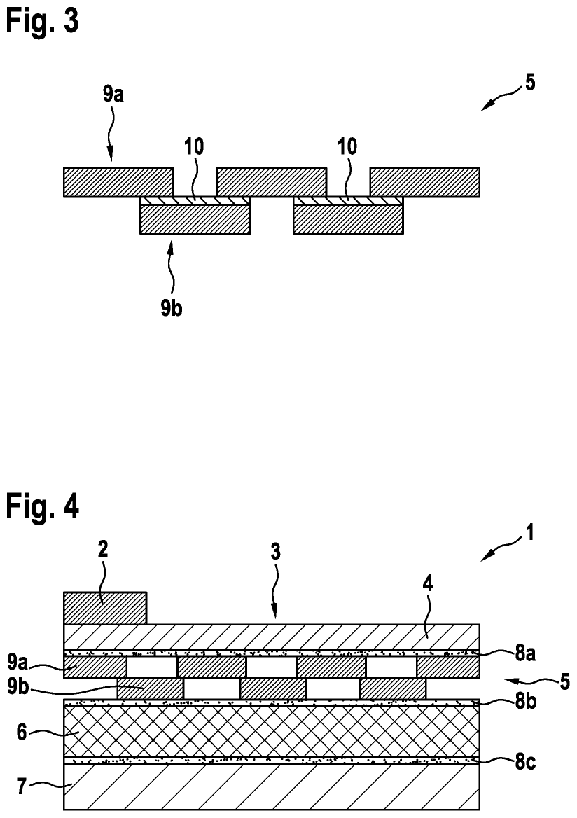

FIGS. 2 and 3 show the thermomechanical door 5 in detail. In FIG. 2, the thermomechanical door 5 is closed. In FIG. 3, the thermomechanical door 5 is opened. The thermomechanical door 5 has two door planes 9a, 9b that are displaceable in relation to each other in order to open or close the thermomechanical door 5, namely an upper door plane 9a and a lower door plane 9b. As can be seen in FIGS. 2 and 3, the lower door plane 9b in this specific embodiment has a phase change material 10 that is arranged between the two door planes 9a, 9b. The phase change material 10 prevents the two door planes 9a, 9b from becoming caught upon opening and closing of the thermomechanical door 5.

In FIG. 2 there is no contact between the upper door plane 9a and the lower door plane 9b. The thermomechanical door 5 is therefore closed, and does not make any heat transfer between the laser emitter 2 and the heat sink layer 7 possible. In FIG. 3 there is contact between the upper door plane 9a and the lower door plane 9b. The thermomechanical door 5 is therefore opened, and makes heat transfer between the laser emitter 2 and the heat sink layer 7 possible.

The thermomechanical door 5 is designed to be opened and closed by lateral contraction and expansion of the two door planes 9a, 9b. The transition between the low temperature situation in FIG. 2 and the high temperature situation in FIG. 3 takes place gradually over a specified temperature range. If the ambient temperature in the temperature range falls over time, the upper door plane 9a and the lower door plane 9b contract laterally, i.e. perpendicularly to the direction of stacking, and finally come out of contact (low temperature situation, FIG. 2). If the ambient temperature in the temperature range rises upwards over time, the upper door plane 9a and the lower door plane 9b expand laterally and finally come into contact in a laterally overlapping manner (high temperature situation, FIG. 3). It should be noted that the thermomechanical door 5 in the closed state has gaps 11, as illustrated in FIG. 2. Then no heat transfer through the thermomechanical door 5 is possible. In the open state of the thermomechanical door 5, the gaps 11, on the other hand, are closed, and the upper door plane 9a and the lower door plane 9b overlap in portions. Then heat transfer through the thermomechanical door 5 is possible. The thermomechanical door 5 is therefore open when heat transfer through it is possible, the two door planes 9a, 9b therefore overlapping in portions, and is closed when no heat transfer through it is possible, the two door planes 9a, 9b therefore being spaced apart from each other by the gaps 11.

In the first embodiment of FIG. 1, a heating element is arranged in the heating element layer 6 between the thermomechanical door 5 and the heat sink layer 7. This element serves to additionally heat the laser emitter 2 if it cannot reach its operating temperature by the waste heat which it itself produces. In this case, the heating element in operation, if required, acts first of all on the lower door plane 9b in order to open the thermomechanical door 5. Then the heating element can transfer its waste heat to the laser emitter 2 through the thermomechanical door 5 in order additionally to heat the laser emitter 2.

In the second embodiment of FIG. 4, the heating element in the heating element layer 6 is replaced by a Peltier element. The Peltier element is therefore arranged therein by way of example between the thermomechanical door 5 and the heat sink layer 7. The Peltier element is designed not only to heat, but if required also to cool, the lower door plane 9b, depending on the situation. In the second embodiment, the laser ceramic layer 4, in a departure from the first embodiment, is formed from AlN. Otherwise, the second embodiment of FIG. 4 corresponds to the first embodiment of FIG. 1.

In specific embodiments of the present invention, not shown, the laser emitter assembly 2 does not have a heating element layer 6. Then the thermoelastic door 5, in particular the lower door plane 9b, is joined directly to the heat sink layer 7, preferably by the second adhesive layer 8b.

In summary, compared with previous solutions for thermal regulation: the thermomechanical door 5 illustrated is less complex, and is more cost-effective; no control means is necessary for its operation; it requires fewer components, in particular no heat spreader, no control means, no electronics; no certification of the component is necessary, and it has greater longevity.

1-10. (canceled)

11. A laser emitter assembly, comprising:
a laser emitter; and
a support for the laser emitter, the support having a multiplicity of layers, wherein one of the layers is a thermomechanical door that is configured to thermally regulate the laser emitter.

12. The laser emitter assembly as recited in claim 11, wherein the thermomechanical door is opened in a high temperature situation and is closed in a low temperature situation.

13. The laser emitter assembly as recited in claim 11, wherein the thermomechanical door has two door planes that are displaceable in relation to each other to open or close the thermomechanical door.

14. The laser emitter assembly as recited in claim 13, wherein the thermomechanical door is configured to be opened and closed by lateral contraction and expansion of the two door planes.

15. The laser emitter assembly as recited in claim 13, wherein at least one of the two door planes includes a phase change material.

16. The laser emitter assembly as recited in claim 15, wherein the phase change material is arranged between the two door planes.

17. The laser emitter assembly as recited in claim 11, wherein the thermomechanical door is arranged between a laser ceramic layer and a heat sink layer.

18. The laser emitter assembly as recited in claim 17, wherein a heating element is arranged between the thermomechanical door and the heat sink layer.

19. The laser emitter assembly as recited in claim 17, wherein a Peltier element is arranged between the thermomechanical door and the heat sink layer.

20. A LiDAR system, comprising:
a laser emitter assembly, the laser emitter assembly including:
a laser emitter; and
a support for the laser emitter, the support having a multiplicity of layers, wherein one of the layers is a thermomechanical door that is configured to thermally regulate the laser emitter; and
a power supply, the laser emitter assembly being operatively connected to the power supply.
